(19) United States
(12) Patent Application Publication
(10) Pub. No.: US 2024/0429586 A1
(43) Pub. Date: Dec. 26, 2024

(54) MARCHAND BALUN AND FREQUENCY MULTIPLIER INCLUDING THE SAME

(71) Applicant: Electronics and Telecommunications Research Institute, Daejeon (KR)

(72) Inventor: Dongwoo KANG, Daejeon (KR)

(73) Assignee: Electronics and Telecommunications Research Institute, Daejeon (KR)

(21) Appl. No.: 18/748,905

(22) Filed: Jun. 20, 2024

(30) Foreign Application Priority Data
Jun. 26, 2023 (KR) 10-2023-0082114

(51) Int. Cl. H01P 3/02; H01P 3/08; H01P 5/10

(52) U.S. Cl. CPC H01P 3/023; H01P 3/081; H01P 5/1007

(57) ABSTRACT

Provided is a Marchand balun and a frequency multiplier including the same. The Marchand balun may include transmission lines and slot lines extending to be proximate to the transmission lines. The transmission lines may include feeding transmission lines and coupled transmission lines connected to the feeding transmission lines. The slot lines may include near-distance slot lines provided to be adjacent to the feeding transmission lines, and far-distance slot lines extending in a direction away from the near-distance slot lines. The feeding transmission lines may be provided to be adjacent to the near-distance slot lines.

### CROSS-REFERENCE TO RELATED APPLICATION

This U.S. non-provisional patent application claims priority under 35 U.S.C. § 119 of Korean Patent Application No. 10-2023-0082114, filed on Jun. 26, 2023, the entire contents of which are hereby incorporated by reference.

### BACKGROUND

The present disclosure herein relates to a frequency multiplier, and more specifically, to a Marchand balun and a frequency multiplier including the same.

Recently, as interest in 5G and 6G communications technologies increases, designs using frequency bands 100 GHz or higher are being actively carried out. However, as the frequency increases, the performance of semiconductor devices gradually deteriorates, which may result in a decrease in transmission output. To overcome this limitation, a structure that increases output in the form of beam forming using multiple channels is being proposed.

### SUMMARY

The present disclosure provides a Marchand balun capable of implementing an ultra-small structure and a frequency multiplier including the same.

An embodiment of the inventive concept provides a Marchand balun. The Marchand balun includes transmission lines and slot lines extending to be proximate to the transmission lines. Here, the transmission lines include feeding transmission lines and coupled transmission lines connected to the feeding transmission lines. The slot lines include near-distance slot lines provided to be adjacent to the feeding transmission lines, and far-distance slot lines extending in a direction away from the near-distance slot lines. The feeding transmission lines are provided to be adjacent to the near-distance slot lines.

In an embodiment, the feeding transmission lines may include a first feeding transmission line and a second feeding transmission line branched from the first feeding transmission line and having a length equal to a length of the first feeding transmission line.

In an embodiment, the coupled transmission lines may include a first coupled transmission line connected to the first feeding transmission line and a second coupled transmission line connected to the second feeding transmission line.

In an embodiment, the near-distance slot lines may include a first near-distance slot line and a second near-distance slot line provided to be adjacent to the first near-distance slot line and parallel to the first near-distance slot line.

In an embodiment, the far-distance slot lines may include a first far-distance slot line connected to the first near-distance slot line, and a second far-distance slot line connected to the second near-distance slot line.

In an embodiment of the inventive concept, a frequency multiplier includes an input distributor, an output distributor separated from the input distributor, comparators provided between the output distributor and the input distributor, and Marchand baluns provided between the input distributor and the comparator. The Marchand baluns include transmission lines including feeding transmission lines and coupled transmission lines connected to the feeding transmission lines, and slot lines including near-distance slot lines extending to be proximate to the coupled transmission lines and provided to be adjacent to the feeding transmission lines and far-distance slot lines extending in a direction away from the near-distance slot lines. The feeding transmission lines are provided to be adjacent to the near-distance slot lines.

In an embodiment, the comparators may include a first comparator connected between any one of the far-distance slot lines and the output distributor; and a second comparator connected between another one of the far-distance slot lines and the output distributor.

In an embodiment, the far-distance slot lines may include a first far-distance slot line connected to the first comparator, and a second far-distance slot line connected to the second comparator.

In an embodiment, the near-distance slot lines may include a first near-distance slot line connected to the first far-distance slot line, and second near-distance slot lines connected to the second far-distance slot line.

In an embodiment, the feeding transmission lines may include a first feeding transmission line adjacent to the first near-distance slot line, and a second feeding transmission line adjacent to the second near-distance slot line.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a diagram illustrating an example of a general Marchand balun;

FIG. 2 is a cross-sectional view illustrating an example of a general semiconductor device;

FIG. 3 is a diagram illustrating an example of a general Marchand balun;

FIG. 4 is a graph illustrating a differential signal obtained by the general Marchand balun 41 of FIG. 3.

FIG. 5 is a diagram illustrating an example of a general frequency multiplier; and

FIG. 6 is a diagram illustrating an example of a frequency multiplier according to the concept of an embodiment of the inventive concept.

### DETAILED DESCRIPTION

Hereinafter, an embodiment of the inventive concept will be described in detail with reference to the accompanying drawings. The advantages and features of an embodiment of the inventive concept and a method for achieving them will become clear by referring to embodiments described in detail below along with the accompanying drawings. However, an embodiment of the inventive concept is not limited to the embodiments set forth herein and may be embodied in different forms. Rather, the embodiments introduced herein are provided so that the disclosed content will be thorough and complete and will fully convey the spirit of the inventive concept to those skilled in the art, and an embodiment of the inventive concept is defined only by the scope of the claims. The same reference numerals refer to the same components throughout the specification.

The terms used in this specification are for describing embodiments and are not intended to limit the embodiment of the inventive concept. In this specification, a singular form includes a plural form unless specifically stated otherwise in the context. The component referred to in terms “comprises” and/or “comprising” as used in the specification do not preclude the existence or addition of a referenced component, or one or more other components, operations and/or elements. In addition, since this is according to an embodiment, reference signs numerals presented according to the order of description are not necessarily limited to that order.

In addition, the embodiments described in this specification will be described with reference to cross-sectional views and/or plan views, which are ideal illustrations of an embodiment of the inventive concept. In the drawings, the thicknesses of films and regions are exaggerated for effective explanation of technical content. Accordingly, the form of the illustration may be modified due to manufacturing technology and/or tolerance, etc. Accordingly, embodiments of the inventive concept are not limited to the specific form shown, but also include changes in form produced according to the manufacturing process.

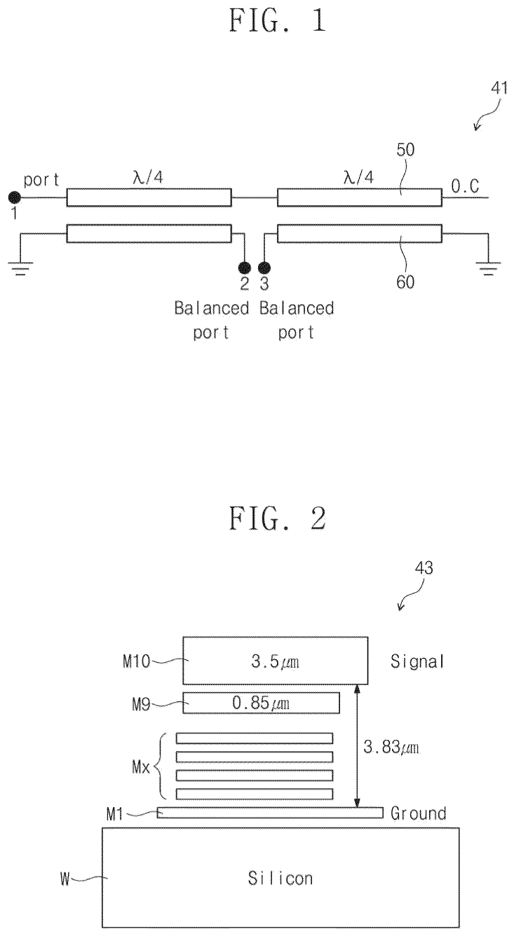

FIG. 1 illustrates an example of a general Marchand balun 41.

Referring to FIG. 1, the general Marchand balun 41 may include a transmission line 50 and slot lines 60.

The transmission line 50 may extend in one direction.

The slot lines 60 may be proximate to the transmission line 50 so as to correspond to ¼ of a frequency wavelength of a transmission signal. The slot lines 60 may be connected between ground and balanced ports. The slot lines 60 may include coupled lines adjacent to the transmission line 50.

In a semiconductor circuit, since a length of the transmission line 50 corresponding to λ/4 significantly increases an area of a chip, the transmission line 50 may be implemented in the form of a meander line to minimize a size of the chip. The general Machan balun 41 may be composed of multiple metal layers in a standard CMOS process. A metal line of an uppermost layer is the thickest in order to implement high Q, such as an inductor, and metal lines below the uppermost layer are used for interconnection and thus may be composed of multiple thin metal lines.

FIG. 2 illustrates an example of a general semiconductor device 43.

Referring to FIG. 2, the general semiconductor device 43 may include a transmission line with a stacked structure of metal layers. For example, the general semiconductor device 43 may have a microstrip or CPW shape. According to one example, the general semiconductor device 43 may include a substrate W, a bottom metal layer M1, middle metal layers Mx, an upper metal layer M9, and an uppermost metal layer M10.

The substrate W may include a silicon wafer, but an embodiment of the inventive concept is not limited thereto.

The bottom metal layer M1 may be provided on the substrate W. The bottom metal layer M1 may include a ground electrode.

The middle metal layers Mx and the upper metal layer M9 may include interconnection lines of the semiconductor device 43, but an embodiment of the inventive concept is not limited thereto.

The uppermost metal layer M10 may be implemented as a microstrip as a signal line. The uppermost metal layer M10 may be formed as slot lines 60 in FIG. 1 to reduce the size of the general semiconductor device. The substrate W, the bottom metal layer M1, the middle metal layer Mx, the upper metal layer M9, and the uppermost metal layer M10 may be connected by via electrodes.

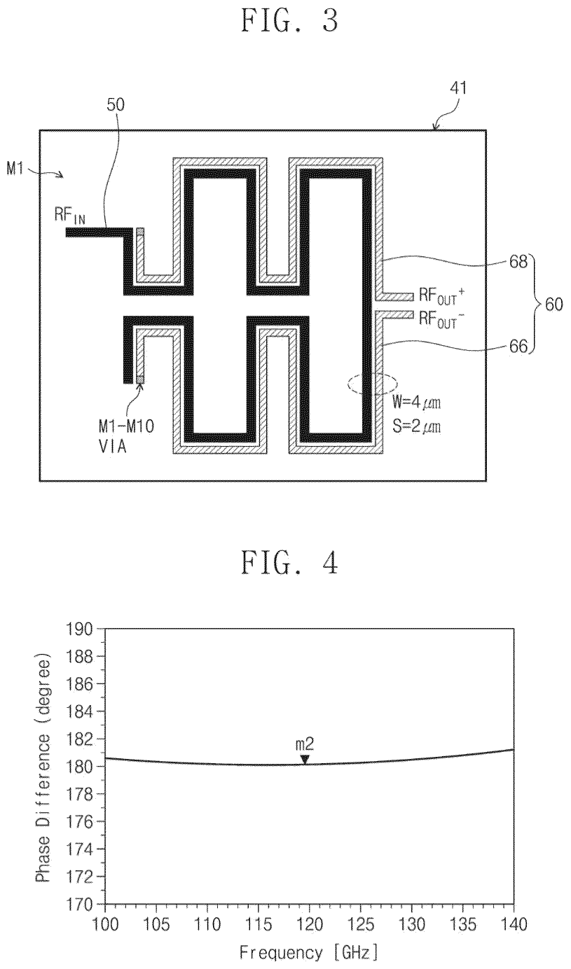

FIG. 3 illustrates an example of the general Marchand balun 41.

Referring to FIG. 3, the transmission line 50 of the general Marchand balun 41 may extend in a meandering shape. The slot lines 60 may be provided to be adjacent to the transmission line 50. The slot lines 60 may include a first slot line 66 and a second slot line 68. The first slot line 66 and the second slot line 68 may be provided at the contour of the transmission line 50. The first slot line 66 and the second slot line 68 may have a symmetrical shape outside the transmission line 50.

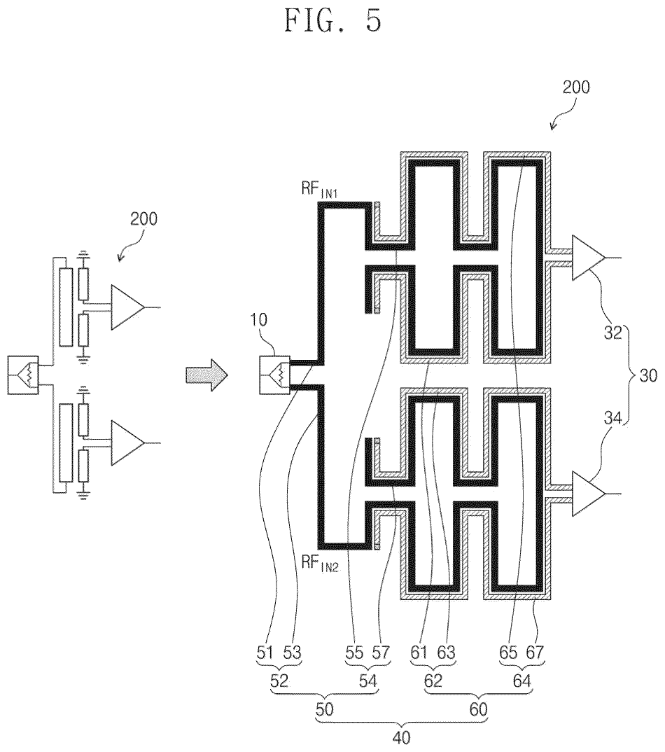

FIG. 4 illustrates a differential signal obtained by the general Marchand balun 41 of FIG. 3.

Referring to FIG. 4, the general Marchand balun 41 may output a differential signal with an error of approximately 1 degree or less for a communication band of approximately 100 GHz to approximately 140 GHz.

FIG. 5 illustrates an example of a general frequency multiplier 200.

Referring to FIG. 5, the general frequency multiplier 200 may include a plurality of Marchand baluns 41.

An input distributor 10 may be connected to the plurality of Marchand baluns 41. The input distributor 10 may receive an input signal and transmit the input signal to the general Machan baluns 41. The general Marchand baluns 41 may include transmission lines 50 and slot lines 60.

The transmission lines 50 may include feeding transmission lines 52 and coupled transmission lines 54. The feeding transmission lines 52 may include a first feeding transmission line 51 and a second feeding transmission line 53.

The slot lines 60 may include near-distance slot lines 62 and far-distance slot lines 64. The near-distance slot lines 62 may include a first near-distance slot line 61 and a second near-distance slot line 63. The far-distance slot lines 64 may include a first far-distance slot line 65 and a second far-distance slot line 67.

The first feeding transmission line 51 and the second feeding transmission line 53 may be connected to be adjacent to the first far-distance slot line 65 and the second far-distance slot line 67 of the far-distance slot lines 64. The lengths of the first feeding transmission line 51 and the second feeding transmission line 53 may increase. If the lengths of the first feeding transmission line 51 and the second feeding transmission line 53 increase, the sizes of the general Marchand balun 41 and the general frequency multiplier 200 may increase.

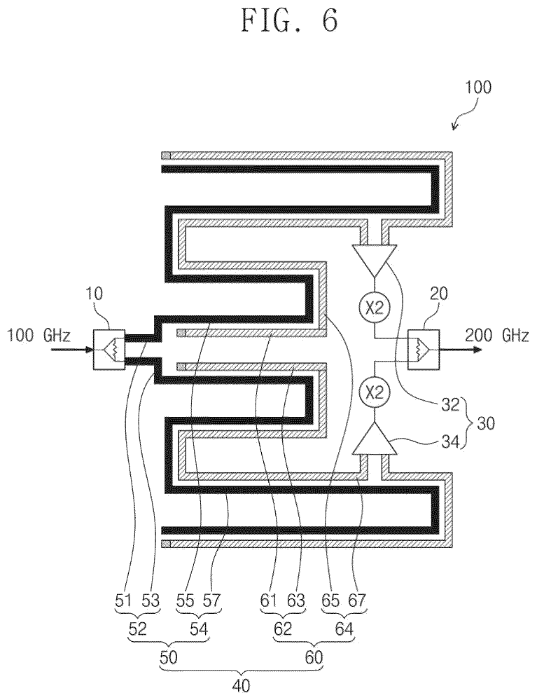

FIG. 6 illustrates an example of a frequency multiplier 100 according to an embodiment of the inventive concept.

Referring to FIG. 6, the frequency multiplier 100 of an embodiment of the inventive concept may include an input distributor 10, an output distributor 20, comparators 30, and Marchand baluns 40.

The input distributor 10 may receive an input signal and transfer the input signal to the Machan baluns 40, the comparators 30, and the output distributor 20.

The output distributor 20 may generate an output signal faster than the input signal by using the input signal and comparison signals of the comparators 30. If the input signal has a frequency of approximately 100 GHz, the output signal may have a frequency of approximately 200 GHz.

The comparators 30 may be provided between the input distributor 10 and the output distributor 20. The comparators 30 may be connected between the Marchand baluns 40 and the output distributor 20 to generate an output signal using an input signal. According to one example, the comparators 30 may include a first comparator 32 and a second comparator 34.

One of the Marchand baluns 40 may be connected between the input distributor 10 and the first comparator 32. Another one of the Marchand baluns 40 may be connected between the input distributor 10 and the second comparator 34. According to one example, the Marchand baluns 40 may include the transmission lines 50 and the slot lines 60.

The transmission lines 50 may receive the input signal. According to one example, the transmission lines 50 may include feeding transmission lines 52 and coupled transmission lines 54. The feeding transmission lines 52 may be connected to the input distributor 10. The feeding transmission lines 52 may receive the input signal and provide it to the coupled transmission lines 54. According to one example, the feeding transmission lines 52 may include a first feeding transmission line 51 and a second feeding transmission line 53.

The first feeding transmission line 51 and the second feeding transmission line 53 may be disposed to be spaced apart from the slot lines 60.

The coupled transmission lines 54 may be connected to the first feeding transmission line 51 and the second feeding transmission line 53. The coupled transmission lines 54 may have a meander shape and extend in a direction away from each other. The coupled transmission lines 54 may include a first coupled transmission line 55 and a second coupled transmission line 57. The first coupled transmission line 55 and the second coupled transmission line 57 may be connected to the first feeding transmission line 51 and the second feeding transmission line 53, respectively.

Slot lines 60 may be provided to be adjacent to the first coupled transmission line 55 and the second coupled transmission line 57. The slot lines 60 may generate an interference signal in response to the input signal. According to one example, the slot lines 60 may include near-distance slot lines 62 and far-distance slot lines 64.

The near-distance slot lines 62 are provided to be adjacent to each other and may be parallel to each other. The near-distance slot lines 62 may include a first near-distance slot line 61 and a second near-distance slot line 63. The first short-range slot line 61 may be provided to be adjacent to the first coupled transmission line 55. The second near-distance slot line 63 may be provided to be adjacent to the second coupled transmission line 57. The second near-distance slot line 63 may be provided between the first near-distance slot line 61 and the second coupled transmission line 57.

The far-distance slot lines 64 may be connected to the comparators. The far-distance slot lines 64 have an asymmetrical shape, and may extend in a direction away from the first near-distance slot line 61 and the second near-distance slot line 63. According to one example, the far-distance slot lines 64 may include a first far-distance slot line 65 and a second far-distance slot line 67. The first far-distance slot line 65 may be connected between the first near-distance slot line 61 and the first comparator 32. The second far-distance slot line 67 may be connected between the second near-distance slot line 63 and the second comparator 34.

The first coupled transmission line 55, the second coupled transmission line 57, the first near-distance slot line 61, the second near-distance slot line 63, the first far-distance slot line 65, and the second far-distance slot line Slot line 67 may minimize or reduce the lengths of the first feeding transmission line 51 and the second feeding transmission line 53.

Accordingly, the frequency multiplier 100 of an embodiment of the inventive concept may reduce the length of the first feeding transmission line 51 and the second feeding transmission line 53 and enable miniaturization of the Marchand Balun 40.

Although the embodiments of the inventive concept have been described with reference to the accompanying drawings, those of ordinary skill in the art to which the embodiment of the inventive concept pertains will understand that the embodiment of the inventive concept may be implemented in other specific forms without changing its technical idea or essential features. Therefore, it should be understood that the embodiments described above are illustrative and not restrictive in all respects.

As described above, the Marchand balun according to an embodiment of the inventive concept may implement an ultra-small structure by providing a feeding transmission line adjacent to near-distance slot lines.

Although the embodiments of the present invention have been described, it is understood that the present invention should not be limited to these embodiments but various changes and modifications can be made by one ordinary skilled in the art within the spirit and scope of the present invention as hereinafter claimed.

What is claimed is:

1. A Marchand balun comprising:
transmission lines; and
slot lines extending to be proximate to the transmission lines, wherein
the transmission lines include
feeding transmission lines, and
coupled transmission lines connected to the feeding transmission lines,
the slot lines include
near-distance slot lines provided to be adjacent to the feeding transmission lines, and
far-distance slot lines extending in a direction away from the near-distance slot lines and the feeding transmission lines, and
the feeding transmission lines are provided to be adjacent to the near-distance slot lines.

2. The Marchand balun of claim 1, wherein
the feeding transmission lines include
a first feeding transmission line, and
a second feeding transmission line branched from the first feeding transmission line and having a length equal to a length of the first feeding transmission line.

3. The Marchand balun of claim 2, wherein
the coupled transmission lines include
a first coupled transmission line connected to the first feeding transmission line, and
a second coupled transmission line connected to the second feeding transmission line.

4. The Marchand balun of claim 1, wherein
the near-distance slot lines include
a first near-distance slot line, and
a second near-distance slot line provided to be adjacent to the first near-distance slot line and parallel to the first near-distance slot line.

5. The Marchand balun of claim 4, wherein
the far-distance slot lines include
a first far-distance slot line connected to the first near-distance slot line, and
a second far-distance slot line connected to the second near-distance slot line.

6. A frequency multiplier comprising:
an input distributor;
an output distributor separated from the input distributor;
comparators provided between the output distributor and the input distributor; and
Marchand baluns provided between the input distributor and the comparator, wherein the Marchand baluns include:
transmission lines including feeding transmission lines and coupled transmission lines connected to the feeding transmission lines, and
slot lines including near-distance slot lines extending to be proximate to the coupled transmission lines and provided to be adjacent to the feeding transmission lines and far-distance slot lines extending in a direction away from the near-distance slot lines, and
wherein the feeding transmission lines are provided to be adjacent to the near-distance slot lines.

7. The frequency multiplier of claim 6, wherein the comparators include:
a first comparator connected between any one of the far-distance slot lines and the output distributor, and
a second comparator connected between another one of the far-distance slot lines and the output distributor.

8. The frequency multiplier of claim 7, wherein the far-distance slot lines include:
a first far-distance slot line connected to the first comparator, and
a second far-distance slot line connected to the second comparator.

9. The frequency multiplier of claim 8, wherein the near-distance slot lines include:
a first near-distance slot line connected to the first far-distance slot line, and
second near-distance slot lines connected to the second far-distance slot line.

10. The frequency multiplier of claim 9, wherein the feeding transmission lines include:
a first feeding transmission line adjacent to the first near-distance slot line, and
a second feeding transmission line adjacent to the second near-distance slot line.
